(19) United States
(12) Patent Application Publication
(10) Pub. No.: US 2014/0291619 A1
(43) Pub. Date: Oct. 2, 2014

(54) METHOD FOR MANUFACTURING ORGANIC LIGHT EMITTING DISPLAY APPARATUS AND ORGANIC LIGHT EMITTING DISPLAY APPARATUS MANUFACTURED BY THE SAME

(71) Applicant: Samsung Display Co., Ltd., Yongin-City (KR)

(72) Inventors: Su-Hwan Lee, Yongin-City (KR); Mu-Hyun Kim, Yongin-City (KR); Ji-Hoon Kang, Yongin-City (KR)

(73) Assignee: Samsung Display Co., Ltd., Yongin-City (KR)

(21) Appl. No.: 13/941,433

(22) Filed: Jul. 12, 2013

(30) Foreign Application Priority Data
Mar. 27, 2013 (KR) 10-2013-0033091

(51) Int. Cl. H01L 27/32; H01L 51/56

(52) U.S. Cl. CPC H01L 27/3248; H01L 51/56
USPC 257/40; 438/34

(57) ABSTRACT

A method for manufacturing an organic light emitting display apparatus includes forming a layer by depositing on a substrate a deposition material emitted from a deposition assembly while conveying the substrate with respect to the deposition assembly. In the forming of the layer, at least two layers of a first layer including a deposition material emitted from a first deposition source, a second layer including deposition materials emitted from the first deposition source and a second deposition source, and a third layer including a deposition material emitted from the second deposition source, are deposited on the substrate by using an angle restriction unit.

### CROSS-REFERENCE TO RELATED PATENT APPLICATION

This application claims priority to and the benefit of Korean Patent Application No. 10-2013-0033091, filed on Mar. 27, 2013, in the Korean Intellectual Property Office, the disclosure of which is incorporated herein in its entirety by reference.

### BACKGROUND

1. Field

The following disclosure relates to a method for manufacturing an organic light emitting display apparatus and an organic light emitting display apparatus manufactured by the method.

2. Description of the Related Art

Of display apparatuses, an organic light emitting display apparatus has been highlighted as a next generation display apparatus due to its wide viewing angle, superior contrast, and fast response speed. An organic light emitting display apparatus has a structure in which an interlayer including a light emitting layer is disposed between a first electrode and a second electrode that are arranged to face each other. The first and second electrodes may be formed in various methods and one of the methods is a deposition method. In order to manufacture an organic light emitting display apparatus by a deposition method, a fine metal mask (FMM) having an opening in a pattern that is the same as or similar to the pattern of the interlayer is provided in close contact to a substrate on which the interlayer is to be formed. Then, a material such as a material of the interlayer is deposited and thus the interlayer in a set or predetermined pattern is formed.

However, according to a comparable deposition method using a FMM, when a large-sized organic light emitting display apparatus is manufactured by using a large-sized substrate or a plurality of organic light emitting display apparatuses are manufactured by using a large-sized mother-substrate, the use of an FMM having a large size is unavoidable. In this case, the mask sags due to its weight and thus an interlayer having a set or predetermined accurate pattern may not be formed. Also, it takes a considerable time to align the large-sized substrate and the large-sized FMM in close contact to each other and then separate them from each other. Thus, a manufacturing time is extended and efficiency of production is lowered.

### SUMMARY

According to an aspect of embodiments of the present invention, a method for manufacturing an organic light emitting display apparatus is provided by which a plurality of deposition layers may be formed, and an organic light emitting display apparatus may be manufactured by the method. According to another aspect of embodiments of the present invention, a method for manufacturing an organic light emitting display apparatus is provided by which a size of a deposition apparatus for manufacturing the organic light emitting display apparatus may be reduced.

According to an embodiment of the present invention, a method of manufacturing an organic light emitting apparatus includes: conveying a transfer unit into a chamber by busing a first conveyer unit configured to penetrate through the chamber when a substrate is fixed on the transfer unit; forming a layer by depositing on the substrate a deposition material emitted from a deposition assembly while conveying the substrate or the deposition assembly with respect to the other of the substrate or the deposition assembly by using the first conveyer unit, the deposition assembly and the substrate being arranged in the chamber to be separated by a set or predetermined distance from each other in the formation of the layer; and returning the transfer unit separated from the substrate by using a second conveyer unit, in which the deposition assembly includes: a first deposition source and a second deposition source for emitting a deposition material, the first and second deposition sources being arranged in a first direction so as to be sequentially accessed when the first conveyer unit conveys the substrate fixed on the transfer unit; a first deposition source nozzle unit arranged in a direction toward the first conveyer unit from the first deposition source and including a deposition source nozzle, and a second deposition source nozzle unit arranged in a direction toward the first conveyer unit from the second deposition source and including a deposition source nozzle; a patterning slit sheet arranged facing the first and second deposition source nozzle units and having a plurality of patterning slits arranged therein in one direction; and an angle restriction unit arranged in the direction toward the first conveyer unit from the first and second deposition sources and configured to guide a path of a deposition material emitted from the first deposition source through the first deposition source nozzle unit to proceed toward the patterning slit sheet and a path of a deposition material emitted from the second deposition source through the second deposition source nozzle unit to proceed toward the patterning slit sheet, in which, in the forming of the layer, at least two layers of a first layer including the deposition material emitted from the first deposition source, a second layer including the deposition material emitted from the first deposition source and the deposition material emitted from the second deposition source, and a third layer including the deposition material emitted from the second deposition source, are deposited on the substrate fixed on the transfer unit by using the angle restriction unit.

In the forming of the layer, the first and second deposition sources may be configured to emit different deposition materials to form the layer.

In the forming of the layer, by using the angle restriction unit, the first layer that includes the deposition material emitted from the first deposition source and does not include the deposition material emitted from the second deposition source may be deposited on the substrate fixed on the transfer unit, and the third layer that includes the deposition material emitted from the second deposition source and does not include the deposition material emitted from the first deposition source may be deposited directly on the first layer.

The angle restriction unit may include a first opening corresponding to the first deposition source nozzle unit and a second opening corresponding to the second deposition source nozzle unit.

The angle restriction unit may include a first angle restriction unit having a first opening corresponding to the first deposition source nozzle unit and a second angle restriction unit having a second opening corresponding to the second deposition source nozzle unit and separated from the first angle restriction unit.

Each of the first and second angle restriction units may be movable in the first direction or a direction opposite to the first direction.

The first deposition source nozzle unit may include a plurality of deposition source nozzles arranged in a second direction that crosses the first direction and is parallel to the substrate fixed on the transfer unit and the second deposition source nozzle unit may include a plurality of deposition nozzles arranged in the second direction, and in a plane perpendicular to the second direction, a first straight line connecting the center of the first opening and the deposition source nozzles of the first deposition source nozzle unit and a second straight line connecting the center of the second opening and the deposition source nozzles of the second deposition source nozzle unit may be not parallel to each other.

The first deposition source nozzle unit may include a plurality of deposition source nozzles arranged in the first direction and the second deposition source nozzle unit may include a plurality of deposition source nozzles arranged in the second direction, and in a plane perpendicular to the second direction crossing the first direction, a first straight line connecting the center of the first opening and the center of the first deposition source nozzle unit and a second straight line connecting the center of the second opening and the center of the second deposition source nozzle unit may not be parallel to each other.

The first deposition source nozzle unit and the second deposition source nozzle unit may be formed in one body.

According to another embodiment of the present invention, an organic light emitting display apparatus includes a substrate, a plurality of thin film transistors on the substrate, a plurality of pixel electrodes electrically connected to the plurality of thin film transistors, a plurality of deposition layers on the plurality of pixel electrodes, and a counter electrode on the plurality of deposition layers, and at least one of the plurality of deposition layers is a linear pattern formed by using the above-described method.

The substrate may have a size of 40 inches or greater.

### BRIEF DESCRIPTION OF THE DRAWINGS

The above and other features and aspects of the present invention will become more apparent by describing in more detail some example embodiments thereof with reference to the attached drawings in which:

FIG. 1 is a plan view schematically illustrating a deposition apparatus according to an embodiment of the present invention;

FIG. 2 is a side view schematically illustrating a deposition unit of the deposition apparatus of FIG. 1;

FIG. 3 is a cross-sectional perspective view schematically illustrating a part of the deposition unit of FIG. 2;

FIG. 4 is a cross-sectional view schematically illustrating a part of the deposition unit of FIG. 2;

FIG. 5 is a conceptual side view schematically illustrating a deposition source of a deposition assembly and an angle restriction unit in the deposition unit of the deposition apparatus of FIG. 1, according to an embodiment of the present invention;

FIG. 6 is a conceptual side view schematically illustrating a deposition source of a deposition assembly and an angle restriction unit in a deposition unit of a deposition apparatus, according to another embodiment of the present invention;

FIG. 7 is a conceptual side view schematically illustrating a deposition source of a deposition assembly and an angle restriction unit in a deposition unit of a deposition apparatus, according to another embodiment of the present invention;

FIG. 8 is a conceptual side view schematically illustrating a deposition source of a deposition assembly and an angle restriction unit in a deposition unit of a deposition apparatus, according to another embodiment of the present invention;

FIG. 9 is a perspective view schematically illustrating a part of a deposition assembly of a deposition apparatus, according to another embodiment of the present invention; and

FIG. 10 is a cross-sectional view schematically illustrating an organic light emitting display apparatus manufactured by using a deposition apparatus, according to an embodiment of the present invention.

### DETAILED DESCRIPTION

The attached drawings for illustrating some example embodiments of the present invention are referred to in order to gain a sufficient understanding of the present invention, the merits thereof, and aspects accomplished by the implementation of the present invention. Hereinafter, aspects of the present invention will be described in more detail by explaining some example embodiments of the invention with reference to the attached drawings. Also, the thickness or size of each layer illustrated in the drawings may be exaggerated for convenience of explanation and clarity. Like reference numerals in the drawings denote like elements.

As used herein, the term “and/or” includes any and all combinations of one or more of the associated listed items. Expressions such as “at least one of,” when preceding a list of elements, modify the entire list of elements and do not modify the individual elements of the list.

In the following description, an x-axis, a y-axis, and a z-axis are not limited to three axes on a rectangular coordinate system and may be interpreted in a broad sense including the above meaning. For example, the x-axis, y-axis, and z-axis may be perpendicular to one another or may indicate different directions that are not perpendicular to one another.

Also, in the following description, when a constituent element such as a layer, a film, a region, or a plate is described to exist on another constituent element, the constituent element may exist directly on the other constituent element or another constituent element may be interposed therebetween.

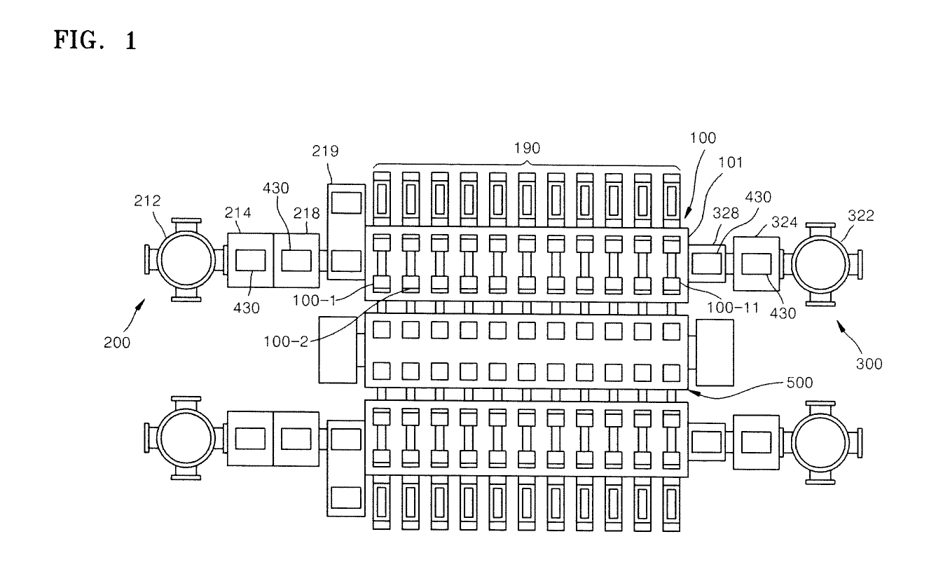

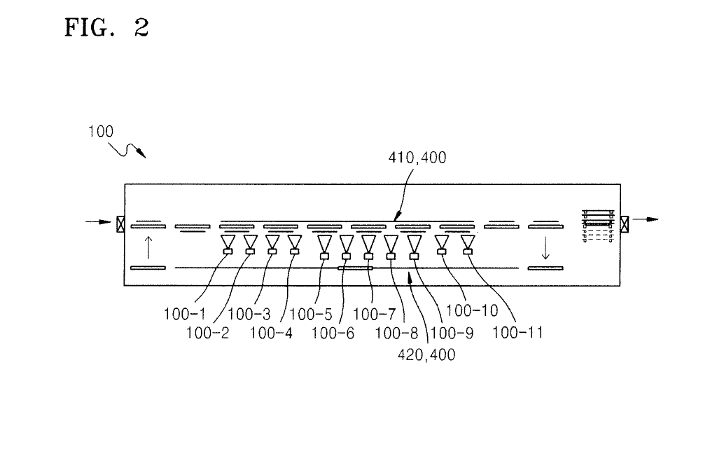

FIG. 1 is a plan view schematically illustrating a deposition apparatus according to an embodiment of the present invention. FIG. 2 is a side view schematically illustrating a deposition unit of the deposition apparatus of FIG. 1.

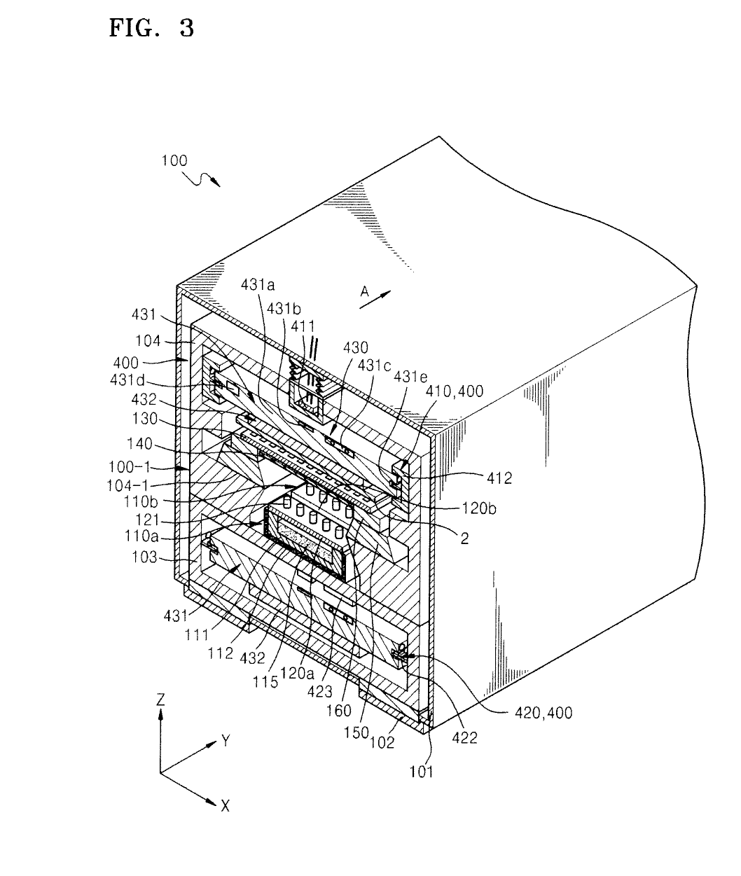

Referring to FIGS. 1 and 2, a deposition apparatus includes a deposition unit 100, a loading unit 200, an unloading unit 300, a conveyer unit 400, and a patterning slit sheet substitution unit 500. The conveyer unit 400 may include a first conveyer unit 410 for conveying in a first direction (e.g., +Y direction) a transfer unit 430 having a substrate 2 (refer to FIG. 3) detachably fixed thereon, and a second conveyer unit 420 for conveying in a reverse direction to the first direction the transfer unit 430 from which the substrate 2 is separated.

The loading unit 200 may include a first rack 212, a carry-in chamber 214, a first reversing chamber 218, and a buffer chamber 219.

The substrates 2 before deposition are provided in plural numbers and stacked on the first rack 212. A carry-in robot holds the substrate 2 from the first rack 212 and accommodates the substrate 2 on the transfer unit 430 that is carried by the second conveyer unit 420 to be located in the carry-in chamber 214. The substrate 2 may be fixed on the transfer unit 430 by a clamp, for example, and the transfer unit 430 having the substrate 2 fixed thereon is conveyed to the first reversing chamber 218. A process of aligning the substrate 2 to the transfer unit 430 before the substrate 2 is fixed on the transfer unit 430 may be performed if necessary.

A first reversing robot reverses the transfer unit 430 in the first reversing chamber 218 located close to the carry-in chamber 214. Here, the carry-in robot places the substrate 2 on an upper surface of the transfer unit 430. The transfer unit 430, in a state in which the substrate 2 having a surface opposite to a surface facing the transfer unit 430 faces upward, is conveyed to the first reversing chamber 218. As the first reversing robot reverses the first reversing chamber 218, the surface of the substrate 2 that is opposite to the surface facing the transfer unit 430 faces downward. In such a state, the first conveyer unit 410 conveys the transfer unit 430 having the substrate 2 fixed thereon.

The unloading unit 300 is configured opposite to the structure of the loading unit 200. In other words, the substrate 2 and the transfer unit 430 passed through the deposition unit 100 are reversed by a second reversing robot in a second reversing chamber 328 and conveyed to a carry-out chamber 324. The substrate 2 is separated from the transfer unit 430 in the carry-out chamber 324. A carry-out robot stacks the substrate 2 separated from the transfer unit 430 on a second rack 322. The second conveyer unit 420 conveys back to the loading unit 200 the transfer unit 430 separated from the substrate 2.

The present invention is not limited to the above structure and the substrate 2 may initially be fixed on a lower surface of the transfer unit 430 to be conveyed. In this case, for example, the first reversing robot of the first reversing chamber 218 and the second reversing robot of the second reversing chamber 328 may not be necessary. Also, the first reversing robot of the first reversing chamber 218 and the second reversing robot of the second reversing chamber 328 may reverse not the first reversing chamber 218 or the second reversing chamber 328, but only the transfer unit 430 having the substrate 2 fixed thereon in the first reversing chamber 218 or the second reversing chamber 328. In this case, a conveyer unit in the first and/or second reversing chambers 218, 328 may be rotated by 180° while the transfer unit 430 is placed on the conveyer unit in the first and/or second reversing chambers 218, 328 that may convey the transfer unit 430 having the substrate 2 fixed thereon. In this case, it may be understood that the conveyer unit in the first and/or second reversing chambers 218, 328 function as the first or second reversing robot. The conveyer unit in the first and/or second reversing chambers 218, 328 may be a part of the first conveyer unit 410 or the second conveyer unit 420.

The deposition unit 100 includes a chamber 101 as illustrated in FIGS. 1 and 2. A plurality of deposition assemblies 100-1, 100-2, . . . , 100-n may be arranged in the chamber 101. Although in FIG. 1 eleven deposition assemblies from a first deposition assembly 100-1 to an eleventh deposition assembly 100-11 are arranged in the chamber 101, the number of the deposition assemblies may vary according to a deposition material and a deposition condition. The chamber 101 may be maintained in a vacuum state or a state close thereto during deposition.

The first conveyer unit 410 conveys (e.g., sequentially conveys) the transfer unit 430 having the substrate 2 fixed thereon to at least the deposition unit 100, or to the loading unit 200, the deposition unit 100, and the unloading unit 300. The second conveyer unit 420 conveys back to the loading unit 200 the transfer unit 430 separated from the substrate 2 in the unloading unit 300. Accordingly, the transfer unit 430 may be circulated by the first conveyer unit 410 and the second conveyer unit 420.

The first conveyer unit 410 may be arranged to penetrate through the chamber 101 when passing through the deposition unit 100. The second conveyer unit 420 may be arranged to transfer the transfer unit 430 separated from the substrate 2.

The first conveyer unit 410 and the second conveyer unit 420 may be vertically arranged. In one embodiment, the transfer unit 430 that undergoes deposition of the substrate 2 while passing through the first conveyer unit 410 is separated from the substrate 2 in the unloading unit 300 and is conveyed back to the loading unit 200 through the second conveyer unit 420 that is arranged under the first conveyer unit 410. Thus, the efficiency of use of space may be improved. Unlike the illustration of FIG. 2, the second conveyer unit 420 may be located above the first conveyer unit 410.

As illustrated in FIG. 1, the deposition unit 100 may include a deposition source substitution portion 190 that is arranged at one side of each deposition assembly 100-1. Although it is not illustrated in the drawings, the deposition source substitution portion 190 may be formed in a cassette form to be drawn outside from each deposition assembly 100-1. Thus, deposition sources 110a and 110b of FIG. 3 of the deposition assembly 100-1 may be easily substituted.

In one embodiment, FIG. 1 illustrates that two deposition apparatuses, each including the loading unit 200, the deposition unit 100, the unloading unit 300, and the conveyer unit 400, are arranged parallel to each other. In this case, the patterning slit sheet substitution unit 500 may be arranged between the two deposition apparatuses. In other words, as the two deposition apparatuses commonly use the patterning slit sheet substitution unit 500, the efficiency of use of space may be improved compared to a case in which the patterning slit sheet substitution unit 500 is separately provided for each of the deposition apparatuses.

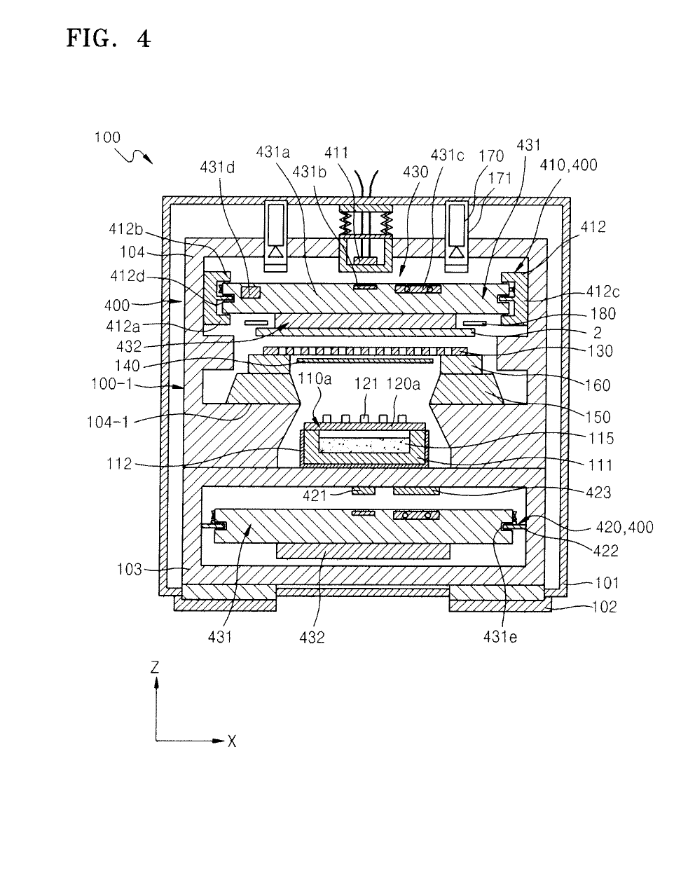

FIG. 3 is a cross-sectional perspective view schematically illustrating a part of the deposition unit 100 of the deposition apparatus of FIG. 1. FIG. 4 is a cross-sectional view schematically illustrating a part of the deposition unit 100 of the deposition apparatus of FIG. 1. Referring to FIGS. 3 and 4, the deposition unit 100 of the deposition apparatus according to the present embodiment includes the chamber 101 and at least one deposition assembly 100-1.

The chamber 101 has an empty box shape and accommodates at least one deposition assembly 100-1 therein. As illustrated in FIGS. 3 and 4, the conveyer unit 400 may be accommodated in the chamber 101 and may extend through the chamber 101, if necessary.

The chamber 101 may accommodate a lower housing 103 and an upper housing 104. In more detail, the lower housing 103 may be arranged on a foot 102 that may be fixed on the ground and the upper housing 104 may be arranged on the lower housing 103. Contacting portions of the lower housing 103 and the chamber 101 may be hermetically sealed so that the inside of the chamber 101 may be completely isolated from the outside. As such, as the lower housing 103 and the upper housing 104 are arranged on the foot 102 that is fixed on the ground, even when the chamber 101 repeats contraction and expansion, the lower housing 103 and the upper housing 104 may be maintained at a fixed position. Thus, the lower housing 103 and the upper housing 104 may perform as a sort of a reference frame in the deposition unit 100.

The deposition assembly 100-1 and the first conveyer unit 410 of the conveyer unit 400 may be arranged in the upper housing 104. The second conveyer unit 420 of the conveyer unit 400 may be arranged in the lower housing 103. While the transfer unit 430 is circulated by the first and second conveyer units 410 and 420, deposition may be continuously performed on the substrate 2 that is fixed on the transfer unit 430. The transfer unit 430 that circulates may include a carrier 431 and an electrostatic chuck 432 coupled to the carrier 431.

The carrier 431 may include a main body portion 431a, a linear motor system magnet (an LMS magnet or a magnetic rail) 431b, a contactless power supply (CPS) module 431c, a power portion 431d, and a guide groove 431e. The carrier 431 may further include a cam follower, as necessary.

The main body portion 431a forms a base portion of the carrier 431 and is formed of a magnetic material such as iron. As such, the carrier 431 may be separated to some extent from a guide portion 412 of the first conveyer unit 410 by an attractive force or a repulsive force between the main body portion 431a of the carrier 431 and a maglev bearing provided in the first conveyer unit 410. Also, the guide groove 431e may be formed at both lateral surfaces of the main body portion 431a. A guide protrusion 412d of the guide portion 412 of the first conveyer unit 410 or a roller guide 422 of the second conveyer unit 420 may be accommodated in the guide groove 431e.

Furthermore, the main body portion 431a may include the magnetic rail 431b arranged along a center line of a progression direction (e.g., Y-axis direction). The magnetic rail 431b of the main body portion 431a may form a linear motor with a coil 411 of the first conveyer unit 410. The transfer unit 430 may be conveyed by the linear motor in a direction A. Accordingly, even when the transfer unit 430 has no separate power source, the transfer unit 430 may be conveyed by a current applied to the coil 411 of the first conveyer unit 410. To this end, the coil 411 may be arranged in plurality numbers in the chamber 101 at a set or predetermined interval (along the Y-axis direction). The coil 411 may be arranged in an atmosphere box so that the coil 411 may be in an atmosphere situation.

The main body portion 431a may include the CPS module 431c and the power portion 431d arranged at one side and the other side of the magnetic rail 431b. The power portion 431d has a rechargeable battery to provide power for the electrostatic chuck 432 to chuck and hold the substrate 2. The CPS module 431c is a wireless charge module to charge the rechargeable battery of the power portion 431d. The second conveyer unit 420 includes a charging track 423 connected to an inverter. When the second conveyer unit 420 conveys the carrier 431, a magnetic field is generated between the charging track 423 and the CPS module 431c so as to supply power to the CPS module 431c and thus the power portion 431d may be charged.

The electrostatic chuck 432 may include a main body formed of ceramic and an electrode buried therein and to which power is applied. The electrostatic chuck 432 may enable the substrate 2 to adhere on a surface of the main body as a high voltage is applied from the power portion 431d of the main body portion 431a to an electrode buried in the main body.

The first conveyer unit 410 may convey the transfer unit 430 configured as above and having the substrate 2 fixed thereon, in the first direction. The first conveyer unit 410 has the coil 411 and the guide portion 412 as described above and may further include a maglev bearing, a gap sensor, etc.

The coil 411 and the guide portion 412 may be arranged on an inner surface of the upper housing 104. For example, the coil 411 may be arranged on an upper inner surface of the upper housing 104 and the guide portion 412 may be arranged on the opposite lateral inner surfaces of the upper housing 104.

The coil 411, as described above, may form the linear motor with the magnetic rail 431b of the main body portion 431a of the transfer unit 430 so as to move the transfer unit 430. When the transfer unit 430 is moved, the guide portion 412 may guide the transfer unit 430 to be conveyed in the first direction. The guide portion 412 may be arranged to pass through the deposition unit 100.

In more detail, the guide portion 412 accommodates the opposite lateral sides of the carrier 431 of the transfer unit 430 to guide the carrier 431 to move along the direction A of FIG. 3. Here, the guide portion 412 may include a first accommodation portion 412a arranged under the carrier 431, a second accommodation portion 412b arranged above the carrier 431, and a connection portion 412c connecting the first accommodation portion 412a and the second accommodation portion 412b. An accommodation groove may be formed by the first accommodation portion 412a, the second accommodation portion 412b, and the connection portion 412c. The guide portion 412 may include a guide protrusion 412d in the accommodation groove.

The maglev bearing may be arranged in each connection portion 412c of the guide portion 412 to correspond to the opposite lateral sides of the carrier 431. The maglev bearing generates an interval between the carrier 431 and the guide portion 412 and thus the carrier 431 may be conveyed along the guide portion 412 in a non-contact manner, that is, without contacting the guide portion 412. The maglev bearing may be arranged in the second accommodation portion 412b of the guide portion 412 to be located above the carrier 431. In this case, the maglev bearing may move along the guide portion 412 without contacting the first accommodation portion 412a or the second accommodation portion 412b and maintaining a certain interval therewith. To check the interval between the carrier 431 and the guide portion 412, the guide portion 412 may include a gap sensor arranged on the first accommodation portion 412a and/or the connection portion 412c to correspond to a lower portion of the carrier 431. A magnetic force of the maglev bearing is changed according to a value measured by the gap sensor and thus the interval between the carrier 431 and the guide portion 412 may be adjusted in real time. In other words, a feedback control using the maglev bearing and the gap sensor enables accurate convey of the carrier 431.

The second conveyer unit 420 returns back to the loading unit 200 the transfer unit 430 from which the substrate 2 is separated in the unloading unit 300 after deposition is completed as the substrate 2 passes through the deposition unit 100. The second conveyer unit 420 may include the coil 421, the roller guide 422, and the charging track 423 which are arranged in the lower housing 103. For example, the coil 421 and the charging track 423 may be arranged in the upper side of the inner surface of the lower housing 103 and the roller guide 422 may be arranged at the opposite lateral sides of the inner surface of the lower housing 103. Although it is not illustrated in FIGS. 3 and 4, the coil 421 may be arranged in an atmosphere box like the coil 411 of the first conveyer unit 410.

Like the coil 411, the coil 421 may form a linear motor with the magnetic rail 431b of the carrier 431 of the transfer unit 430. The transfer unit 430 may be conveyed by the linear motor in a direction (e.g., −Y direction) opposite to the first direction.

The roller guide 422 guides the carrier 431 to move in the direction opposite to the first direction. The roller guide 422 may be arranged to penetrate through the deposition unit 100. The roller guide 422 may support the cam follower arranged at the opposite lateral sides of the carrier 431 of the transfer unit 430 and guide the transfer unit 430 to be conveyed in the opposite direction to the first direction.

Since the second conveyer unit 420 returns the transfer unit 430 having the substrate 2 separated therefrom in a direction back to the loading unit 200, high positional accuracy is not needed for the transfer unit 430 that is conveyed, compared to the first conveyer unit 410 that conveys the transfer unit 430 having the substrate 2 fixed thereon so that deposition may be performed on the substrate 2. Thus, the maglev function is applied to the first conveyer unit 410 that needs high positional accuracy of the transfer unit 430 that is conveyed. A comparable roller method is applied to the second conveyer unit 420. Accordingly, the structure of the deposition apparatus may be simplified and the manufacturing costs thereof may be reduced. The maglev function may be applied to the second conveyer unit 420, if necessary.

The deposition assembly 100-1 being separated a set or predetermined distance from the substrate 2 performs deposition of a material on the substrate 2 while the first conveyer unit 410 conveys the substrate 2 fixed on the transfer unit 430 in the first direction. A more detailed structure of the deposition assembly 100-1 is described below.

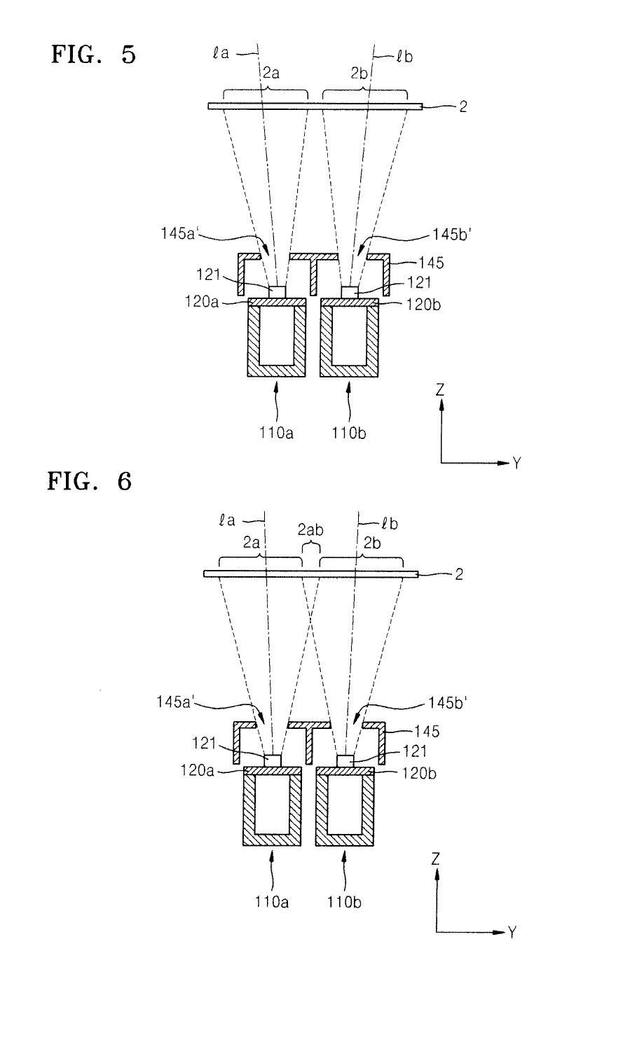

Each deposition assembly 100-1 may include first and second deposition sources 110a and 110b, first and second deposition source nozzle units 120a and 120b, a patterning slit sheet 130, an angle restriction unit (refer to 145 of FIG. 5), a blocking member 140, a first stage 150, a second stage 160, a camera 170, and a sensor 180. Most elements illustrated in FIGS. 3 and 4 may be arranged in the chamber 101 where vacuum is appropriately maintained. This is to secure linearity of a deposition material.

The first and second deposition sources 110a and 110b each may emit a deposition material. The deposition assembly 100-1 of the deposition apparatus according to the present embodiment includes the first deposition source 110a and the second deposition source 110b which are arranged in the first direction to be sequentially accessed when the first conveyer unit 410 conveys the substrate 2 fixed on the transfer unit 430. Also, unlike the illustrations of FIGS. 3 and 4, three or more deposition sources may be arranged. The first and second deposition sources 110a and 110b are arranged below the substrate 2 and emit the deposition material 115 in a direction toward the substrate 2, for example, upwardly in a +Z direction, as the deposition material 115 contained in a crucible 111 evaporates/sublimates. In more detail, the deposition sources 110a and 110b each may include the crucible 111 containing the deposition material 115 and a heater 112 that heats the crucible 111 to evaporate the deposition material 115 in the crucible 111.

The first and second deposition source nozzle units 120a and 120b, each having deposition source nozzles 121 formed thereon, are arranged in the +Z direction toward the first conveyer unit 410, that is, the direction toward the substrate 2 from the deposition sources 110a and 110b. In more detail, the first deposition source nozzle unit 120a is arranged in the direction toward the first conveyer unit 410 from the first deposition source 110a, whereas the second deposition source nozzle unit 120b is arranged in the direction toward the first conveyer unit 410 from the second deposition source 110b. In FIGS. 3 and 4, the first and second deposition source nozzle units 120a and 120b each have a plurality of the deposition source nozzles 121.

Although FIGS. 3 and 4 illustrate that the first deposition source nozzle unit 120a and the second deposition source nozzle unit 120b are separated from each other, the present invention is not limited thereto. For example, the first deposition source 110a and the second deposition source 110b are accommodated in one vessel having an open upper side. One deposition source nozzle unit including deposition source nozzles corresponding to the first and second deposition sources 110a and 110b may be disposed in the vessel. In other words, the first and second deposition source nozzle units 120a and 120b may be formed in one body. In the following description, a case in which the first and second deposition source nozzle units 120a and 120b are separately provided will be described.

The patterning slit sheet 130 may be arranged to face the first and second deposition source nozzle units 120a and 120b and may have a structure in which a plurality of patterning slits are formed in one direction (e.g., X-axis direction). The patterning slit sheet 130 may be disposed between the deposition source 110 and the substrate 2. The deposition material 115 evaporated from the first and second deposition sources 110a and 110b may pass through the first and second deposition source nozzle units 120a and 120b and the patterning slit sheet 130 and may be deposited on the substrate 2 that is a target deposition object. When a uniform deposition layer is formed on an entire surface of the substrate 2, the patterning slit sheet 130 may have an opening extending along the X-axis instead of the patterning slits.

The patterning slit sheet 130 may be manufactured by etching used for a method of manufacturing a comparable fine metal mask (FMM), particularly, a stripe type mask. The patterning slit sheet 130 may be arranged to be separated by a set or predetermined distance from the first and second deposition sources 110a and 110b (and the first and second deposition source nozzle units 120a and 120b coupled thereto).

In order to make the deposition material 115 emitted from the first and second deposition sources 110a and 110b pass through the first and second deposition source nozzle units 120a and 120b and the patterning slit sheet 130 to be deposited on the substrate 2 in a desired pattern, the inside of the chamber 101 is maintained in a high vacuum state that is the same as or similar to the case of FMM deposition. Also, the temperature of the patterning slit sheet 130 is sufficiently lower than those of the first and second deposition sources 110a and 110b (e.g., about 100° C. or less). This is because a thermal expansion problem of the patterning slit sheet 130 due to the high temperature may be reduced only when the temperature of the patterning slit sheet 130 is sufficiently low. In other words, when the temperature of the patterning slit sheet 130 increases, the size and/or the position of a patterning slit of the patterning slit sheet 130 are deformed due to the thermal expansion and thus the deposition may be performed on the substrate 2 in a pattern different from a preset pattern.

The substrate 2 that is a target deposition object is arranged in the chamber 101. The substrate 2 may be a substrate for a flat panel display device and may be a large-sized substrate such as a mother glass for forming a plurality of flat panel display devices.

As described above, in the comparable deposition method using an FMM, the size of an FMM is the same as that of a substrate. Thus, as the size of a substrate increases, the size of an FMM increases and thus the manufacturing of an FMM becomes difficult and a mask sagging phenomenon occurs due to the weight of the FMM. Accordingly, an interlayer having a preset accurate pattern may not be formed.

However, in a case of the deposition apparatus according to the present embodiment, deposition is performed as the deposition assembly 100-1 and the substrate 2 move relatively to each other. In more detail, while the first conveyer unit 410 conveys the substrate 2 fixed on the transfer unit 430 in the first direction, the deposition assembly 100-1 separated by a set or predetermined distance from the substrate 2 performs deposition of a material on the substrate 2. In other words, deposition is performed in a scanning method as the substrate 2 arranged to face the deposition assembly 100-1 is conveyed in the direction A of FIG. 3. Although FIGS. 3 and 4 illustrate that deposition is performed as the substrate 2 is conveyed in the first direction within the chamber 101, the present invention is not limited thereto. In this regard, a variety of modifications are available. For example, while the position of the substrate 2 is fixed, the deposition assembly 100-1 may perform deposition while moving in the −Y direction.

Thus, in the deposition apparatus according to the present embodiment, the size of the patterning slit sheet 130 may be much smaller than that of the comparable FMM. In other words, in the deposition apparatus according to the present embodiment, since deposition is performed continuously, that is, in the scanning method, while moving in the Y-axis direction, even when the length of the patterning slit sheet 130 in the Y-axis direction is much shorter than the length of the substrate 2 in the Y-axis direction, the deposition may be sufficiently performed with respect to most of the entire surface of the substrate 2.

As such, since the size of the patterning slit sheet 130 may be made much smaller than that of the comparable FMM, the manufacturing of the patterning slit sheet 130 is made easy. In other words, the patterning slit sheet 130 having a relatively small size is an enhancement compared to the large-sized FMM in all processes including an etching process to manufacture the patterning slit sheet 130 and subsequent processes such as precision tensile and welding process, transfer and washing process, etc. Such an enhancement becomes more remarkable as the size of a display device to be manufactured increases.

On the other hand, while the first conveyer unit 410 conveys the substrate 2 fixed on the transfer unit 430 in the first direction, the deposition assembly 100-1 that is separated by a set or predetermined distance from the substrate 2 performs deposition of a material on the substrate 2. This means that the patterning slit sheet 130 is arranged to be separated by a set or predetermined distance from the substrate 2. In the comparable deposition apparatus using the FMM, it is a problem when the FMM and the substrate contact each other, causing a defect. In the deposition apparatus according to the present embodiment, however, such a problem may be effectively prevented. Also, since a time to contact the substrate and the mask close to each other in the process is not needed, a manufacturing speed may be remarkably increased.

The upper housing 104, as illustrated in FIGS. 3 and 4, may have an accommodation portion 104-1 that protrudes toward the opposite lateral sides of the first and second deposition sources 110a and 110b and the first and second deposition source nozzle units 120a and 120b. The first stage 150 and the second stage 160 are arranged on the accommodation portion 104-1 and the patterning slit sheet 130 may be arranged on the second stage 160.

The first stage 150 may adjust the position of the patterning slit sheet 130 in the X-axis direction and the Y-axis direction. In other words, the first state 150 is provided with a plurality of actuators and may move the patterning slit sheet 130 in the X-axis direction and the Y-axis direction with respect to the upper housing 104. The second stage 160 may adjust the position of the patterning slit sheet 130 in a Z-axis direction. For example, the second stage 160 is provided with an actuator and may adjust the position of the patterning slit sheet 130 with respect to the first stage 150, that is, in the Z-axis direction with respect to the upper housing 104.

As the position of the patterning slit sheet 130 is adjusted with respect to the substrate 2 by using the first stage 150 and the second stage 160, alignment, particularly, real-time alignment, between the substrate 2 and the patterning slit sheet 130 may be performed.

In addition, the upper housing 104, the first stage 150, and the second stage 160 may simultaneously perform a function of guiding a movement path of a deposition material to prevent dispersion of the deposition material emitted through the deposition source nozzles 121. In other words, the path of the deposition material is limited by the upper housing 104, the first stage 150, and the second stage 160 and thus the movement of the deposition material in the X-axis direction may be restricted.

The deposition assembly 100-1 may further include the camera 170 and the sensor 180 for alignment. The sensor 180 may be a confocal sensor. The camera 170 may check in real time a first mark formed on the patterning slit sheet 130 and a second mark formed on the substrate 2 and generate data to make the patterning slit sheet 130 and the substrate 2 accurately aligned on an X-Y plane. The sensor 180 may generate data about the interval between the patterning slit sheet 130 and the substrate 2 to maintain the patterning slit sheet 130 and the substrate 2 at an appropriate interval.

As such, the interval between the patterning slit sheet 130 and the substrate 2 may be measured in real time by using the camera 170 and the sensor 180 and also the real-time alignment of the patterning slit sheet 130 and the substrate 2 may be available. Accordingly, the positional precision of a pattern may be further improved.

The blocking member 140 may be arranged between the patterning slit sheet 130 and the first and second deposition sources 110a and 110b to prevent or substantially prevent a material from being deposited in a non-film forming area of the substrate 2. Although it is not illustrated in FIGS. 3 and 4, the blocking member 140 may include two plates neighboring each other. Since the non-film forming area of the substrate 2 is blocked by the blocking member 140, the deposition of a material in the non-film forming area of the substrate 2 may be effectively and easily prevented or substantially prevented without a separate structure.

FIG. 5 is a conceptual side view schematically illustrating the first and second deposition sources 110a and 110b of the deposition assembly 100-1 and the angle restriction unit 145 in the deposition unit 100 of the deposition apparatus of FIG. 1. Referring to FIG. 5, the angle restriction unit 145 may be arranged in a direction (e.g., +Z direction) of the first conveyer unit 410 from the first and second deposition sources 110a and 110b. The angle restriction unit 145 may guide a path of a deposition material that is emitted from the first deposition source 110a via the first deposition source nozzle unit 120a and proceeds toward the patterning slit sheet 130 and the substrate 2. The angle restriction unit 145 may also guide a path of a deposition material that is emitted from the second deposition source 110b via the second deposition source nozzle unit 120b and proceeds toward the patterning slit sheet 130 and the substrate 2.

According to the guide of the angle restriction unit 145, at least two layers of a first layer including the deposition material emitted from the first deposition source 110a, a second layer including the deposition material emitted from the first deposition source 110a and the deposition material emitted from the second deposition source 110b, and a third layer including the deposition material emitted from the second deposition source 110b, may be deposited on the substrate 2 that is fixed on the transfer unit 430.

The angle restriction unit 145 guides a path of the deposition material in a variety of methods. For example, as illustrated in FIG. 5, the angle restriction unit 145 may have a shape encompassing each of the first and second deposition sources 110a and 110b. Also, the angle restriction unit 145 has a first opening 145a′ corresponding to the deposition source nozzles 121 of the first deposition source nozzle unit 120a and a second opening 145b′ corresponding to the deposition source nozzles 121 of the second deposition source nozzle unit 120b. The angle restriction unit 145 may guide a path of the deposition material by adjusting a positional relationship between the first opening 145a′ and the deposition source nozzles 121 of the first deposition source nozzle unit 120a and a positional relationship between the second opening 145b′ and the deposition source nozzles 121 of the second deposition source nozzle unit 120b.

As illustrated in FIGS. 3 and 5, the deposition source nozzles 121 of the first deposition source nozzle unit 120a may be arranged crossing the first direction and along a second direction, for example, the X-axis direction, parallel to the substrate 2 fixed on the transfer unit 430. The deposition source nozzles 121 of the second deposition source nozzle unit 120b may be arranged along the second direction. In this case, in a plane (e.g., Y-Z plane) that is perpendicular to the second direction, a first straight line la connecting between the center of the first opening 145a′ and the deposition source nozzles 121 of the first deposition source nozzle unit 120a and a second straight line lb connecting between the center of the second opening 145b′ and the deposition source nozzles 121 of the second deposition source nozzle unit 120b may not be parallel to each other.

In more detail, with respect to a plane (e.g., Z-X plane) that is perpendicular to the first direction, the first straight line la may be gradually inclined in a direction (e.g., −Y direction) opposite to the first direction as away from the deposition source nozzles 121 of the first deposition source nozzle unit 120a toward the substrate 2. With respect to a plane (e.g., Z-X plane) that is perpendicular to the first direction, the second straight line VD may be gradually inclined in the first direction as away from the deposition source nozzles 121 of the second deposition source nozzle unit 120b toward the substrate 2.

In one embodiment, when the angle restriction unit 145 having the above shape guides the deposition material emitted from the first deposition source 110a and the deposition material emitted from the second deposition source 110b as illustrated in FIG. 5, the deposition material emitted from the first deposition source 110a and the deposition material emitted from the second deposition source 110b are not mixed with each other until arriving at the substrate 2.

In this state, when the substrate 2 fixed on the transfer unit 430 is conveyed by the first conveyer unit 410 in the first direction, a portion 2b of the substrate 2 in the first direction first passes over the first deposition source 110a. While the substrate 2 passes over the first deposition source 110a, the portion 2b of the substrate 2 in the first direction is deposited with the deposition material emitted from the first deposition source 110a.

Next, when the portion 2b of the substrate 2 in the first direction passes over the second deposition source 110b, a portion 2a of the substrate 2 in the opposite direction to the first direction is located above the first deposition source 110a and is deposited with the deposition material emitted from the first deposition source 110a. Simultaneously, the portion 2b of the substrate 2 in the first direction is deposited with the deposition material emitted from the second deposition source 110b. In this case, in the portion 2b of the substrate 2 in the first direction, the third layer that is a layer of the deposition material emitted from the second deposition source 110b is formed on the first layer, that is, a layer of the deposition material emitted from the first deposition source 110a that is already deposited. As such, the first and third layers may be formed on the substrate 2 as the substrate 2 passes through the deposition assembly 100-1 including the first and second deposition sources 110a and 110b. When the first and second deposition sources 110a and 110b emit different deposition materials, the first and third layers formed of different materials may be formed on the substrate 2.

If the angle restriction unit 145 does not exist, even when a single deposition assembly, for example, the deposition assembly 100-1, includes a plurality of deposition sources, for example, the first and second deposition sources 110a and 110b, is used, only one layer formed of mixed deposition materials emitted from the first and second deposition sources 110a and 110b may be formed on the substrate 2 that is conveyed above the deposition assembly 100-1. Accordingly, when a plurality of layers are to be formed on the substrate 2, the deposition apparatus should be provided with a plurality of deposition assemblies, for example, the deposition assemblies 100-1 through 100-11 of FIG. 2, that correspond to the number of the layers and are separated from one another.

However, since the deposition apparatus according to the present embodiment includes the angle restriction unit 145, a plurality of layers may be formed on the substrate 2 by using the single deposition assembly 100-1. Accordingly, the number of the deposition assemblies that are provided in the deposition apparatus may be reduced and thus miniaturization of the deposition apparatus and reduction of the manufacturing cost may be available.

As described above with reference to FIG. 5, the angle restriction unit 145 guides such that the first layer that includes the deposition material emitted from the first deposition source 110a and does not include the deposition material emitted from the second deposition source 110b is deposited on the substrate 2 fixed on the transfer unit 430, and the third layer that includes the deposition material emitted from the second deposition source 110b and does not include the deposition material emitted from the first deposition source 110a is deposited directly on the first layer. The present invention is not limited thereto and the angle restriction unit 145 may control an emission angle of the deposition material in a variety of methods.

FIG. 6 is a conceptual side view schematically illustrating the first and second deposition sources 110a and 110b of the deposition assembly 100-1 and the angle restriction unit 145 in the deposition unit 100 of a deposition apparatus, according to another embodiment of the present invention. Referring to FIG. 6, with respect to a plane (e.g., Y-Z plane) that is perpendicular to the second direction, in the angle restriction unit 145, the first straight line la connecting between the center of the first opening 145a′ and the deposition source nozzles 121 of the first deposition source nozzle unit 120a and the second straight line lb connecting between the center of the second opening 145b′ and the deposition source nozzles 121 of the second deposition source nozzle unit 120b may still not be parallel to each other. However, by decreasing the angle between the first straight line la and the second straight line lb compared to that illustrated in FIG. 5, the deposition material emitted from the first deposition source 110a and the deposition material emitted from the second deposition source 110b may be deposited in a mixed state on a portion 2ab of the substrate 2 between the first and second deposition sources 110a and 110b on the substrate 2.

In other words, as illustrated in FIG. 6, when the substrate 2 passes over the first and second deposition sources 110a and 110b, a multilayer film including the first layer including the deposition material emitted from the first deposition source 110a, the second layer disposed on the first layer including the deposition material emitted from the first deposition source 110a and the deposition material emitted from the second deposition source 110b, and the third layer disposed on the second layer and including the deposition material emitted from the second deposition source 110b, may be formed on the second substrate 2. In this case, the thicknesses of the first, second, and third layers may be adjusted by adjusting the angle between the first straight line la and the second straight line lb.

In the above description, a case that the single deposition assembly 100-1 includes the first and second deposition sources 110a and 110b, that is, two deposition sources, is described. However, the present invention is not limited thereto.

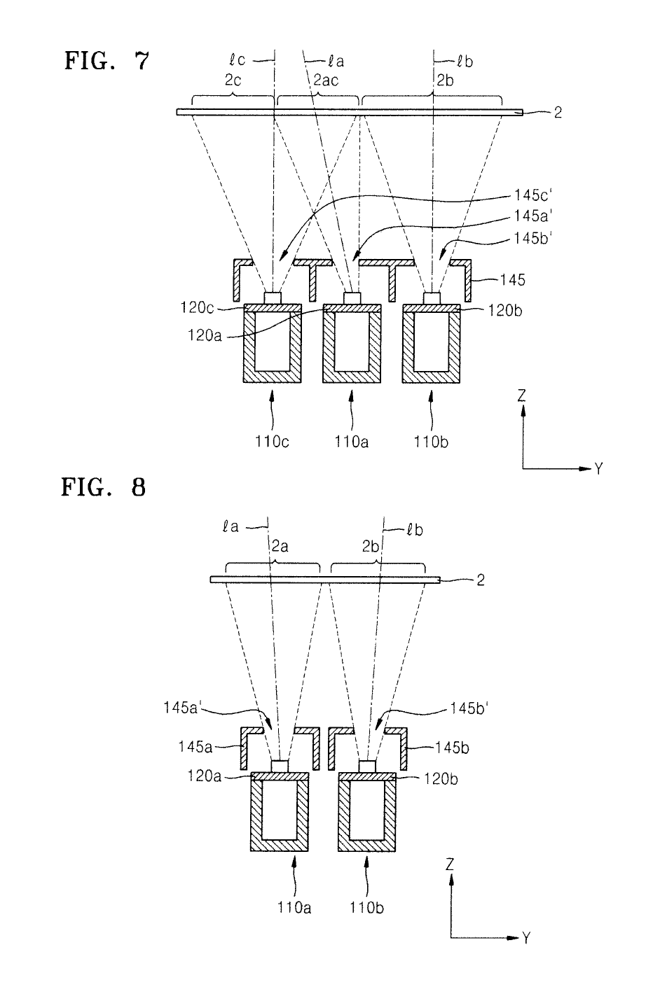

FIG. 7 is a conceptual side view schematically illustrating the first and second deposition sources 110a, 110b, and a third deposition source 110c of the deposition assembly 100-1 and the angle restriction unit 145 in the deposition unit 100 of the deposition apparatus, according to another embodiment of the present invention. In this case, the angle restriction unit 145 may have a third opening 145c′ corresponding to the third deposition source 110c in addition to the first and second openings 145a′ and 145b′, and a third straight line lc connecting between the center of the third opening 145c′ and the deposition source nozzles 121 of a third deposition source nozzle unit 120c of the third deposition source 110c. A portion 2ac of the substrate 2 is located above the first deposition source 110a and the third deposition source 110c and is deposited with the deposition material emitted from the first deposition source 110a and the third deposition source 110c. Also, a portion 2c of the substrate 2 is located above the third deposition source 110c and is deposited with the deposition material emitted from the third deposition source 110c.

Referring to FIG. 7, a case is illustrated in which, while the substrate 2 is conveyed in the first direction, a layer including the deposition material emitted from the third deposition source 110c, a layer in which the deposition material emitted from the third deposition source 110c and the deposition material emitted from the first deposition source 110a are mixed with each other, and a layer including the deposition material emitted from the second deposition source 110b are sequentially formed on the substrate 2. In FIG. 7, the first straight line la and the second straight line lb are not parallel to each other and thus a multilayer film, not a single layer film, may be deposited on the substrate 2 by the first and second deposition sources 110a and 110b arranged close to each other in the single deposition assembly 100-1.

FIG. 8 is a conceptual side view schematically illustrating the first and second deposition sources 110a and 110b of the deposition assembly 100-1 and the angle restriction unit 145 in the deposition unit 100 of the deposition apparatus, according to an embodiment of the present invention. Referring to FIG. 8, the angle restriction unit 145 may include a first angle restriction unit 145a having the first opening 145a′ corresponding to the first deposition source nozzle unit 120a and a second angle restriction unit 145b separated from the first angle restriction unit 145a and having the second opening 145b′ corresponding to the second deposition source nozzle unit 120b. The first angle restriction unit 145a and the second angle restriction unit 145b each may be moved in the first direction or the opposite direction thereto. Accordingly, a thickness of a multilayer film or the number of layers of a multilayer film, for example, a double layer film or a triple layer film, deposited on the substrate 2 may be easily adjusted by freely adjusting the angel between the first straight line la and the second straight line lb. In this case, the first angle restriction unit 145a may have a structure of encompassing the first deposition source 110a and the second angle restriction unit 145b may have a structure of encompassing the second deposition source 110b.

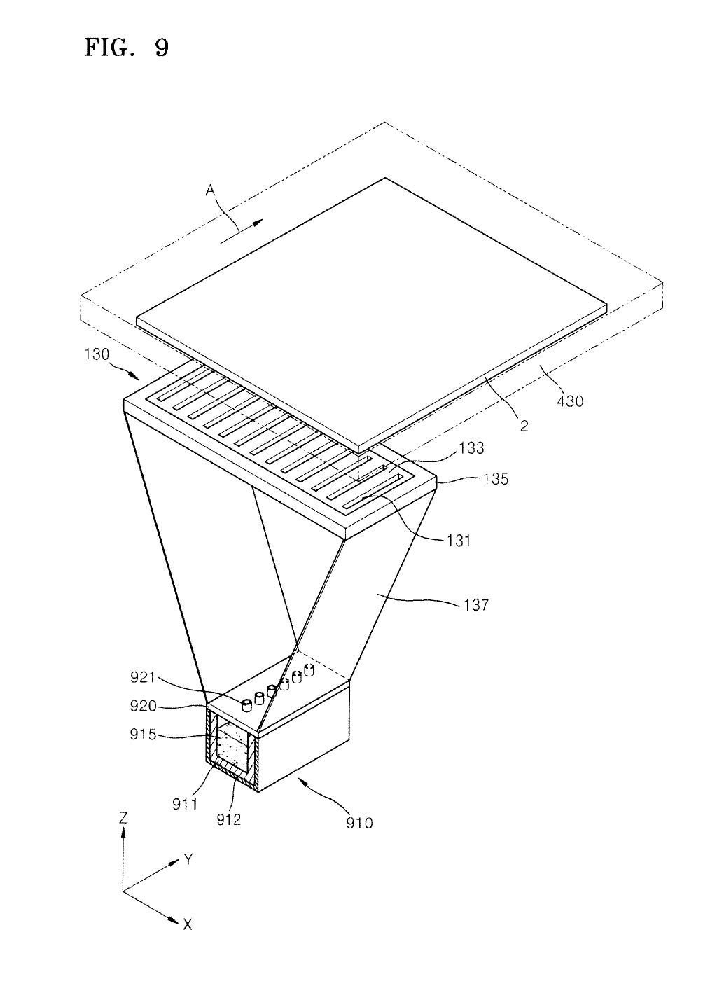

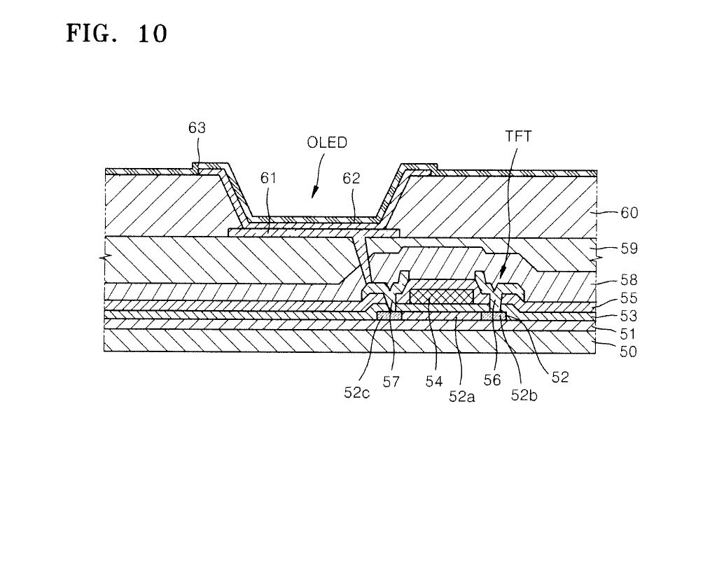

FIG. 9 is a perspective view schematically illustrating a part of a deposition assembly of the deposition apparatus, according to another embodiment of the present invention. In the deposition apparatuses according to the above-described embodiments, the first and second deposition source nozzle units 120a and 120b of the deposition assembly 100-1 are described to have the deposition source nozzles 121 arranged in the second direction, for example, the X-axis direction, crossing the first direction and parallel to the substrate 2 fixed on the transfer unit 430. However, in the deposition apparatus according to the present embodiment, a plurality of deposition source nozzles 921 of a deposition source nozzle unit 920 are arranged in the first direction (e.g., the Y-axis direction).

In manufacturing an organic light emitting display apparatus, when an interlayer including a light emitting layer is formed, a common layer that is incorporated across an entire display area may be formed or a pattern layer disposed only in a preset area of the display area may be formed.

When a common layer is formed, as described above, as the first and second deposition source nozzle units 120a and 120b include the deposition source nozzles 121 arranged in the second direction crossing the first direction and parallel to the substrate 2 fixed on the transfer unit 430, uniformity in the thickness of the common layer being formed may be improved. When a pattern layer is formed, as illustrated in FIG. 9, as the deposition source nozzle unit 920 of the deposition assembly includes the deposition source nozzles 921 arranged in the first direction, one deposition source nozzle 921 may be disposed in the second direction crossing the first direction and parallel to the substrate 2 fixed on the transfer unit 430 in the plane (e.g., Z-X plane) perpendicular to the first direction. Accordingly, when the pattern layer is formed, generation of shadow may be greatly reduced.

Although FIG. 9 illustrates only one deposition source and one deposition source nozzle unit, a first deposition source and a second deposition source may be sequentially arranged in the first direction, a plurality of deposition source nozzles of a first deposition source nozzle unit of the first deposition source may be arranged in the first direction, and the a plurality of deposition source nozzles of a second deposition source nozzle unit may be arranged in the first direction. In this case, in the plane (e.g., Y-Z plane) that is perpendicular to the second direction crossing the first direction and parallel to the substrate 2 fixed on the transfer unit 430, a first straight line connecting between the center of a first opening of an angle restriction unit and the center of the first deposition source nozzle unit and a second straight line connecting between the center of a second opening of an angle restriction unit and the center of the second deposition source nozzle unit may not be parallel to each other and thus a multilayer film, not a single layer film, may be deposited on the substrate 2 as the substrate 2 passes through a single deposition assembly.

The patterning slit sheet 130 as described above may have a shape as illustrated in FIG. 9. In other words, as illustrated in FIG. 9, the patterning slit sheet 130 may have a frame 135 of a shape like a window frame, for example, and a sheet 133 coupled to the frame 135 by welding, for example. A plurality of patterning slits 131 may be formed in the sheet 133 in the X-axis direction, for example. A deposition material contained in a crucible 911 of a deposition source 910 is evaporated by a heater 912 and emitted through a deposition source nozzle 921 of a deposition source nozzle unit 920. The deposition material may be accommodated on the substrate 2 via the patterning slit 131 of the patterning slit sheet 130. The deposition source 910 and/or the deposition source nozzle unit 920 and the patterning slit sheet 130 may be coupled by a connection portion 137.

Although only the deposition apparatus is mainly described in the above, the present invention is not limited thereto. For example, a method of manufacturing an organic light emitting display apparatus using the above deposition apparatus may belong to the scope of the present invention.

In the method of manufacturing an organic display device according to another embodiment, while the substrate 2 is fixed on the transfer unit 430, the transfer unit 430 is conveyed into the chamber 101 by the first conveyer unit 410 that is provided to penetrate through the chamber 101. Next, while the deposition assembly 100-1 and the substrate 2 arranged in the chamber 101 to be separated by a set or predetermined distance from each other, the substrate 2 is relatively conveyed by the first conveyer unit 410 with respect to the deposition assembly 100-1. In this state, the deposition material emitted from the deposition assembly 100-1 is deposited on the substrate 2, thereby forming a layer. Then, the transfer unit 430 separated from the substrate 2 is returned by the second conveyer unit 420 that is provided to penetrate through the chamber 101. Thus, the transfer unit 430 may be circulated by the first and second conveyer units 410 and 420.

In the method of manufacturing an organic display device according to another embodiment, the deposition assembly may have the structure of the deposition assembly of the deposition apparatuses according to the above-described embodiments. In this case, the forming of the layer may be forming of at least two layers of the first layer including the deposition material emitted from the first deposition source 110a, the second layer including the deposition material emitted from the first deposition source 110a and the deposition material emitted from the second deposition source 110b, and the third layer including the deposition material emitted from the second deposition source 110b, on the substrate 2 fixed on the transfer unit 430 by using the angle restriction unit 145. In this case, the forming of the layer may be forming of a layer by emitting different deposition materials from the first and second deposition sources 110a and 110b.

Also, in the forming of the layer, for example, as illustrated in FIG. 5, the first layer that includes the deposition material emitted from the first deposition source 110a and does not include the deposition material emitted from the second deposition source 110b is deposited on the substrate 2 fixed on the transfer unit 430, and the third layer that includes the deposition material emitted from the second deposition source 110b and does not include the deposition material emitted from the first deposition source 110a is formed directly on the first layer, by using the angle restriction unit 145. According to the above method, a multilayer film is formed on the substrate 2 by using a small deposition apparatus and thus an organic light emitting display apparatus may be efficiently manufactured.

FIG. 10 is a cross-sectional view schematically illustrating an organic light emitting display apparatus manufactured by using the deposition apparatus of FIG. 1. Referring to FIG. 10, various constituent elements of the organic light emitting display apparatus are formed on a substrate 50. The substrate 50 may be the substrate 2 of FIG. 3 or a part of the substrate 2 obtained by cutting the same. The substrate 50 may be formed of a transparent material, for example, a glass member, a plastic member, or a metal member.

A common layer such as a buffer layer 51, a gate insulation film 53, and an interlayer insulation film 55 may be formed on an entire surface of the substrate 50. A patterned semiconductor layer 52 including a channel area 52a, a source contact area 52b, and a drain contact area 52c may be formed on the substrate 50. Also, with the above patterned semiconductor layer, a gate electrode 54, a source electrode 56, and a drain electrode 57, which are constituent elements of a thin film transistor (TFT), may be formed on the substrate 50.

Furthermore, a protection film 58 covering the TFT and a planarization film 59 disposed on the protection film 58 and having an upper surface that is almost planar may be formed on the entire surface of the substrate 50. An organic light emitting display (OLED) device including a patterned pixel electrode 61, an counter electrode 63 approximately corresponding to the entire surface of the substrate 50, and an interlayer 62 having a multilayer structure including a light emitting layer and provided between the pixel electrode 61 and the counter electrode 63 may be formed on the planarization film 59. Unlike the illustration of FIG. 10, a partial layer of the interlayer 62 may be a common layer approximately corresponding to the entire surface of the substrate 50, whereas other partial layer thereof may be a pattern layer that is patterned corresponding to the pixel electrode 61. The pixel electrode 61 may be electrically connected to the TFT through a via hole. A pixel define film 60 covering an edge of the pixel electrode 61 and having an opening that defines each pixel area may be formed on the planarization film 59 approximately corresponding to the entire surface of the substrate 50.

In the organic light emitting display apparatus, at least parts of the constituent elements may be formed by using the deposition apparatus according to the above-described embodiments. For example, the interlayer 62 may be formed by using the deposition apparatus according to the above-described embodiments. For example, a hole injection layer (HIL), a hole transport layer (HTL), an emission layer (EML), an electron transport layer (ETL), and an electron injection layer (EIL), which may be included in the interlayer 62, may be formed by using the deposition apparatus according to the above-described embodiments.

In other words, when each layer of the interlayer 62 is formed, the deposition assembly having the deposition source, the deposition source nozzle unit, the patterning slit sheet, and the angle restriction unit may perform deposition while any one of the deposition assembly and the substrate is moved relatively with respect to the other one when the deposition assembly is arranged to be separated by a set or predetermined distance from the substrate having even a target deposition substrate, in more detail, the pixel electrode 61, formed thereon.

If the patterning slit sheet includes the patterning slits 131 arranged in the X-axis direction as illustrated in FIG. 9, to form one layer of the interlayer 62 by using the pattern slit sheet, the layer may have a linear pattern. The layer may be, for example, a light emitting layer.

As described above, when deposition is performed on a large-sized substrate, the deposition apparatus of FIG. 1 may accurately perform deposition in a preset area. For example, even for an organic light emitting display apparatus having a substrate of 40 inches or greater, the interlayer 62 may be accurately formed and thus a high quality organic light emitting display apparatus may be embodied.

As described above, in the method for manufacturing an organic light emitting display apparatus and an organic light emitting display apparatus according to embodiments of the present invention, a plurality of deposition layers may be formed and a size of a deposition apparatus for manufacturing the organic light emitting display apparatus may be reduced.

While this invention has been particularly shown and described with reference to some example embodiments thereof, it will be understood by those skilled in the art that various changes in form and details may be made therein without departing from the spirit and scope of the invention as defined by the appended claims, and equivalents thereof.

What is claimed is:

1. A method of manufacturing an organic light emitting apparatus, the method comprising:
conveying a transfer unit into a chamber by busing a first conveyer unit configured to penetrate through the chamber when a substrate is fixed on the transfer unit;
forming a layer by depositing on the substrate a deposition material emitted from a deposition assembly while conveying the substrate or the deposition assembly with respect to the other of the substrate or the deposition assembly by using the first conveyer unit, the deposition assembly and the substrate being arranged in the chamber to be separated by a distance from each other in forming the layer; and
returning the transfer unit separated from the substrate by using a second conveyer unit,
wherein the deposition assembly comprises:
a first deposition source and a second deposition source for emitting a deposition material, the first and second deposition sources being arranged in a first direction so as to be sequentially accessed when the first conveyer unit conveys the substrate fixed on the transfer unit;
a first deposition source nozzle unit arranged in a direction toward the first conveyer unit from the first deposition source and including a deposition source nozzle, and a second deposition source nozzle unit arranged in the direction toward the first conveyer unit from the second deposition source and including a deposition source nozzle;
a patterning slit sheet arranged facing the first and second deposition source nozzle units and having a plurality of patterning slits; and
an angle restriction unit arranged in the direction toward the first conveyer unit from the first and second deposition sources and configured to guide a path of a deposition material emitted from the first deposition source through the first deposition source nozzle unit to proceed toward the patterning slit sheet and a path of a deposition material emitted from the second deposition source through the second deposition source nozzle unit to proceed toward the patterning slit sheet, and
wherein, in the forming of the layer, at least two layers of a first layer including the deposition material emitted from the first deposition source, a second layer including the deposition material emitted from the first deposition source and the deposition material emitted from the second deposition source, and a third layer including the deposition material emitted from the second deposition source, are deposited on the substrate fixed on the transfer unit by using the angle restriction unit.

2. The method of claim 1, wherein, in the forming of the layer, the first and second deposition sources are configured to emit different deposition materials to form the layer.

3. The method of claim 1, wherein, in the forming of the layer, by using the angle restriction unit, the first layer that includes the deposition material emitted from the first deposition source and does not include the deposition material emitted from the second deposition source is deposited on the substrate fixed on the transfer unit, and the third layer that includes the deposition material emitted from the second deposition source and does not include the deposition material emitted from the first deposition source is deposited directly on the first layer.

4. The method of claim 1, wherein the angle restriction unit comprises a first opening corresponding to the first deposition source nozzle unit and a second opening corresponding to the second deposition source nozzle unit.

5. The method of claim 1, wherein the angle restriction unit comprises a first angle restriction unit having a first opening corresponding to the first deposition source nozzle unit, and a second angle restriction unit having a second opening corresponding to the second deposition source nozzle unit and separated from the first angle restriction unit.

6. The method of claim 5, wherein each of the first and second angle restriction units is movable in the first direction or a direction opposite to the first direction.

7. The method of claim 4,
wherein the first deposition source nozzle unit comprises a plurality of deposition source nozzles arranged in a second direction that crosses the first direction and is parallel to the substrate fixed on the transfer unit, and the second deposition source nozzle unit comprises a plurality of deposition nozzles arranged in the second direction, and
wherein, in a plane perpendicular to the second direction, a first straight line connecting a center of the first opening and the deposition source nozzles of the first deposition source nozzle unit, and a second straight line connecting the center of the second opening and the deposition source nozzles of the second deposition source nozzle unit are not parallel to each other.

8. The method of claim 4, wherein the first deposition source nozzle unit comprises a plurality of deposition source nozzles arranged in the first direction, and the second deposition source nozzle unit comprises a plurality of deposition source nozzles arranged in the second direction, and
in a plane perpendicular to the second direction crossing the first direction, a first straight line connecting a center of the first opening and a center of the first deposition source nozzle unit and a second straight line connecting a center of the second opening and a center of the second deposition source nozzle unit are not parallel to each other.

9. The method of claim 1, wherein the first deposition source nozzle unit and the second deposition source nozzle unit are formed in one body.

10. An organic light emitting display apparatus comprising:
a substrate;
a plurality of thin film transistors on the substrate;
a plurality of pixel electrodes electrically connected to the plurality of thin film transistors;
a plurality of deposition layers on the plurality of pixel electrodes; and
a counter electrode on the plurality of deposition layers,
wherein at least one of the plurality of deposition layers is a linear pattern formed by using the method of claim 1.

11. The organic light emitting display apparatus of claim 10, wherein the substrate has a size of 40 inches or greater.
